(19) United States
(12) Patent Application Publication
(10) Pub. No.: US 2011/0312182 A1
(43) Pub. Date: Dec. 22, 2011

(54) METHOD AND APPARATUS FOR CHEMICAL-MECHANICAL PLANARIZATION

(75) Inventors: Leonard John Borucki, Mesa, AZ (US); Yasa Adi Sampurno, Tucson, AZ (US); Ara Philipossian, Tucson, AZ (US)

(73) Assignee: ARACA, INC., Tucson, AZ (US)

(21) Appl. No.: 13/225,086

(22) Filed: Sep. 2, 2011

Related U.S. Application Data
(63) Continuation-in-part of application No. PCT/US2010/034975, filed on May 14, 2010.
(60) Provisional application No. 61/510,877, filed on Jul. 22, 2011.

(51) Int. Cl. H01L 21/306; C09K 3/14; C09G 1/02; B24B 27/00

(52) U.S. Cl. 438/693; 451/559; 51/298; 257/E21.23

(57) ABSTRACT

A method and apparatus for performing chemical-mechanical planarization (CMP) is disclosed, which in one embodiment includes a CMP tool for polishing a semiconductor wafer. The CMP tool includes a slurry mixture that has slurry beads. The slurry beads are formed of a polymer material. The slurry beads are used to remove summits and non-uniformities on the semiconductor wafer. In some embodiments the CMP tool includes a counter-face that replaces the polishing pad of a conventional CMP tool. In some embodiments the counter-face is made of polycarbonate. In another embodiment a slurry mixture for use with a CMP tool is disclosed. The slurry mixture includes slurry beads, where each of the slurry beads has a diameter of between 0.1 and 1000 microns, or in some embodiments a diameter of between 10 and 50 microns.

### CROSS-REFERENCE TO RELATED APPLICATIONS

This application is a continuation-in-part of the earlier Patent Cooperation Treaty patent application to Borucki, et al entitled “Method for CMP Using Pad in a Bottle,” serial number PCT/US2010/034975, filed May 14, 2010; this application also claims priority to U.S. Provisional Patent Application to Borucki, et al entitled “Method for CMP Using Pad in a Bottle,” Ser. No. 61/510,877, filed Jul. 22, 2011 the disclosure of which is hereby incorporated entirely herein by reference.

### BACKGROUND OF THE INVENTION

The disclosed invention relates to a method and apparatus for performing chemical-mechanical planarization (CMP) wherein beads or particles of a polymer material are suspended in the polishing slurry mixture to provide asperities for the polishing process and in some cases the polishing pad is partially or wholly replaced by a counter-face made of a smooth hard material.

### FIELD OF THE INVENTION

When integrated circuits (ICs) are constructed in the semiconductor industry and related industries, a process called chemical-mechanical planarization, or CMP, is typically used numerous times during manufacturing to planarize the wafer surface on which the circuits are being built. Planarization is essential for the construction of the wiring, or interconnects, that is used in circuits, and can also be an important step in forming transistors and other electronic components. Non-planar surfaces present difficulties for the application of lithographic tools, which are used to create patterns on the wafer and which have a limited depth of focus. CMP in the last 20 years has become a key technology enabling essentially unlimited complexity in integrated circuit design. IC fabrication facilities therefore typically have large numbers of CMP tools and incur substantial costs running them.

In a conventional CMP process a silicon wafer with integrated circuit chips under construction is held upside down by a polishing head. The polishing head presses the wafer against a large rotating polishing platen with a controlled force. The platen is covered with a thin polyurethane polishing pad, typically up to a meter in diameter and 1-2 millimeters (mm) thick. Microscopic protuberances on the pad surface, also known as asperities or summits, make contact with the wafer, and, with the assistance of polishing slurry containing chemistry and abrasive particles, effect the removal of material from the wafer surface.

The polishing slurry is usually applied at a slow, continuous rate to the polishing pad in the vicinity of the wafer using a drip or spray system. Because polyurethane pad asperities may be irreversibly deformed by contact with the wafer, or may be abraded by the slurry particles, the polishing pad surface must be continuously renewed in order to sustain a stable CMP process. Polishing pad renewal is usually accomplished with a circular diamond cutting tool, called a pad conditioner or pad dresser. During CMP tool operation, the pad conditioner is swept back and forth across the pad surface under a light applied load. The diamonds cut the pad surface at a slow rate, eliminating old asperities and creating new ones in the process. Since the pad conditioner cuts the pad, conditioning the pad produces small particles of pad debris, many of which are washed off of the pad surface, but some of which also come into contact with the wafer. The latter are suspected to be a source of defects that affect integrated circuit viability and reliability. Polishing pad conditioning also gradually thins the polishing pad, which eventually forces pad replacement.

Conventional CMP processing, as described above, has several weaknesses. One is that the pad asperities so essential to the process are in fact not very well-controlled. We find that asperities on commercial pad surfaces produced by commercial conditioners under normal polishing conditions can be highly variable in height, in curvature or sharpness at the point of contact, and in area density on the pad. As a result, contact area distributions are highly variable. Substantial evidence of pad fragments from the conditioner that are either loosely connected to the pad (hanging chads) or are totally disconnected (pad debris) are also observed.

Pad surface variability becomes visible to the user of CMP in the form of wafer-to-wafer variations in the material removal rate, in removal rate non-uniformity across the wafer surface, and in micro-scratches on the polished surface. Pad surface variability will become an increasing concern over time since some materials being considered for incorporation in future generations of ICs are very fragile and easily damaged by the occasional large asperity. Thus it is desirable to have an apparatus and method for performing CMP where the asperities that perform the polishing are controlled in height, position, and shape.

Cost is also an issue in an industry that has had to produce increasing performance at continuously decreasing cost for several decades. Polishing pads typically cost a few hundred to in excess of a thousand dollars each. A commercial polisher may use up to three pads simultaneously, and the useful life for each pad is often only two or three days of continuous use. Each CMP tool therefore uses hundreds of pads annually, and since wafer fabrication facilities can have dozens of tools, the total cost for pads alone is substantial. Since it can take several hours to remove a pad and install a new one, and dozens of monitor wafers to qualify the new pad for production worthiness, the engineering and product loss cost of tool down time can be significant. Thus it is desirable to have an apparatus and method for performing CMP which is more cost effective than the current system, which requires the continual purchase and replacement of polishing pads.

Similar issues occur with pad conditioners, which cost several hundred dollars each. Even though pad conditioners are often constructed with thousands of diamonds embedded in a metal or ceramic matrix, it has been found through extensive studies for diamond conditioner manufacturers as explained in U.S. patent application Ser. No. 12/359,772, incorporated herein by reference in its entirety and made a part hereof, that only a few hundred diamonds actively cut the polishing pad surface and that only a small number of these, the aggressive diamonds, account for most of the cut rate. The small number of aggressive diamonds can result in large differences in the rate at which nominally identical conditioners cut the pad. When a few of the aggressive diamonds wear out or break, the conditioner has to be replaced even though 99.99% of the diamonds are still in usable condition. Because of the small number of diamonds involved, and sometimes because of the chemical environment, conditioner replacement usually occurs after a few tens of hours of use. Thus, conditioners also create both process variability and a substantial consumables cost. Thus it is desirable to have an apparatus and method for performing CMP that does not require the use of a costly and inefficient diamond pad conditioner.

### SUMMARY OF THE INVENTION

The disclosed invention relates to a method and apparatus for performing chemical-mechanical planarization (CMP) wherein beads or particles of a polymer material are suspended in the slurry to provide asperities for the polishing process and in some cases the polishing pad is partially or wholly replaced by a counter-face made of a smooth hard material.

Disclosed is a chemical-mechanical planarization (CMP) tool for polishing a semiconductor wafer or other work piece. The CMP tool includes a slurry mixture comprising slurry beads, and a counter-face which holds the slurry beads against the semiconductor wafer. The slurry beads each have a diameter of between 0.1 and 1000 microns. In some embodiments the slurry beads are formed of a polymer material. In some embodiments the slurry beads are formed of a man-made polymer material. In some embodiments the slurry beads each have a diameter of between 1 and 100 microns. In some embodiments the slurry beads each have a diameter of between 10 and 50 microns. In some embodiments the slurry beads each have approximately the same diameter. In some embodiment the CMP tool includes a counter-face, where the counter-face is formed of polycarbonate. In some embodiments the counter-face is formed of quartz. In some embodiments the counter-face according to the invention is formed of polyethylene. In some embodiments the counter-face according to the invention is formed of polyurethane. In some embodiments the slurry beads develop a slurry bead static charge that opposes a counter-face static charge of the counter-face. In some embodiments the counter-face is hydrophilic. In some embodiments the counter-face is hydrophobic. In some embodiments the slurry beads each have a diameter that is approximately equal to the distance between the counter-face and the semiconductor wafer. In some embodiments the CMP tool according to the invention is a conventional CMP tool that has been converted to a CMP tool according to the invention.

Disclosed is a slurry mixture for use with a chemical-mechanical planarization tool, where the slurry mixture includes slurry beads that include a polymer material. In some embodiments the slurry beads are formed of a man-made polymer material. In some embodiments the slurry beads each have a diameter of between 0.1 and 1000 microns. In some embodiments the slurry beadseach have a diameter of between 1 and 100 microns. In some embodiments the slurry beads each have a diameter of between 10 and 50 microns. In some embodiments the slurry beads each have approximately the same diameter. In some embodiments the slurry beads are made of polyurethane. In some embodiments the slurry beads are spherical or ovoid shaped. In some embodiments the diameter of the slurry beads varies according to a predetermined distribution function. In some embodiments the concentration of slurry beads in the slurry mixture is between 0.001 and 30 weight percent. In some embodiments the concentration of slurry beads in the slurry mixture is between 0.1 and 30 weight percent. In some embodiments the concentration of slurry beads in the slurry mixture is between 5 and 20 weight percent. In some embodiments the slurry beads include a compressible material.

A method of polishing a semiconductor wafer using a chemical-mechanical planarization tool is disclosed. The method includes the step of polishing the semiconductor wafer using a slurry mixture, where the slurry mixture includes slurry beads, and where the slurry beads each have a diameter of between 0.1 and 1000 microns. In some embodiments the slurry beads each have a diameter between 1 and 100 microns. In some embodiments the slurry beads each have a diameter between 10 and 50 microns. In some embodiments the slurry beads include a polymer material. In some embodiments the slurry beads are formed of a man-made polymer material. In some embodiments the CMP tool includes a counter-face formed of polycarbonate. In some embodiments the counter-face is formed of quartz. In some embodiments the counter-face according to the invention is formed of polyethylene. In some embodiments the counter-face according to the invention is formed of polyurethane. In some embodiments the counter-face is hydrophilic. In some embodiments the counter-face is hydrophobic. In some embodiments the slurry beads each have a diameter that is approximately equal to the distance between the counter-face and the semiconductor wafer. In some embodiments the concentration of slurry beads in the slurry mixture is between 0.001 and 30 weight percent. In some embodiments the concentration of slurry beads in the slurry mixture is between 0.1 and 30 weight percent. In some embodiments the concentration of slurry beads in the slurry mixture is between 5 and 20 weight percent. In some embodiments the method of polishing a semiconductor wafer according to the invention includes the step of treating the counter-face such that an attractive force is generated between the counter-face and the slurry beads. In some embodiments the method of polishing a semiconductor wafer according to the invention includes converting a prior art CMP tool to a CMP tool according to the invention. In some embodiments converting a prior art CMP tool to a CMP tool according to the invention includes removing the polishing pad from the CMP tool. In some embodiments converting a prior art CMP tool to a CMP tool according to the invention includes installing a counter-face according to the invention in place of the polishing pad.

### DESCRIPTION OF DRAWINGS

FIG. 1 shows an embodiment of chemical-mechanical planarization (CMP) tool 110 according to the invention.

FIG. 2 shows a side view of CMP tool 110 of FIG. 1.

FIG. 3 shows an expanded cross-section view of the interface between a semiconductor wafer surface to be polished 142 and a typical polishing pad 123 with asperities, with conventional slurry mixture 140 occupying the space between surface to be polished 142 and polishing surface 127.

FIG. 4 shows an expanded cross-section view of the interface between semiconductor wafer 117 surface to be polished 142 and counter-face 122 of CMP tool 110 of FIG. 1, showing slurry mixture 120 according to the invention with slurry beads 130 (4 of 19 labeled) occupying gap 146 between counter-face 122 and surface to be polished 142.

FIG. 5 shows several embodiments of slurry beads 130 according to the invention, where in these embodiments each slurry bead 130 has a diameter of D₃.

FIG. 6 shows method 170 of polishing a semiconductor wafer using a CMP tool according to the invention.

### DETAILED DESCRIPTION OF EMBODIMENTS OF THE INVENTION

The disclosed invention relates to a method and apparatus for performing chemical-mechanical planarization (CMP) wherein beads or particles of a polymer material are suspended in the polishing slurry mixture to provide asperities for the polishing process and in some cases the polishing pad is partially or wholly replaced by a counter-face made of a smooth hard material.

The inventors of the disclosed invention have made various and earnest researches into the problems described above and have discovered an apparatus and method that can eliminate the asperity-containing polishing pad and conditioner from the CMP process. The polishing pad asperities are replaced with microscopic polymer slurry beads or particles comprising suitably durable and chemically stable materials such as polyethylene, with a diameter approximately comparable to the size of conventional polishing pad asperities between about 0.1 micron and 1000 microns. Prior art slurry mixtures include much smaller particles, in the range of approximately 1 to 100 nanometers, with the belief that the smaller particles were best for the polishing process. In the method and apparatus of the invention the conventional polishing pad can be replaced with a counter-face surface made of a durable chemically stable material such as polycarbonate. The slurry beads are suspended in polishing slurry, where they come into contact with the wafer surface by being pressed between the wafer surface to be polished and the counter-face as the wafer is moved across the polishing layer by the CMP tool. Polishing occurs in much the same way as with the use of a conventional polishing pad with polishing asperities. Since the size of the slurry beads, the size distribution, and the concentration of slurry beads in the slurry can easily be adjusted, it is possible to control the height, curvature, and area density of the “summits” that come in contact with the wafer. This can substantially reduce the process variability associated with conventional polishing pad asperity contact since there is almost total control of the contact conditions. In some embodiments of the invention a conventional prior art CMP tool is modified by the addition of a slurry mixture according to the invention. In some embodiments of the invention a conventional prior art CMP tool is modified by the replacement of the polishing pad with a counter-face according to the invention.

The method and apparatus of the invention has been developed in response to the present state of the art, and, in particular, in response to the problems and needs in the art that have not yet been fully solved by currently available CMP methods and tools. The disclosed invention provides a method and tool for reducing the level of defects to a semiconductor wafer and for reducing the inconvenience, inefficiency and process waste to the CMP process caused by the use of polishing pads with fixed asperities that require conditioning discs. Thus it is an overall objective of the invention to provide a method and apparatus for CMP that achieves a reduction in the level of defects to the semiconductor wafer and a reduction of the inconvenience, inefficiency and process waste to the CMP process caused by the use of polishing pads with fixed asperities and the associated conditioning discs used during the CMP process. The disclosed invention allows the consistent production of a high quality semiconductor wafer product at a cost lower than what is possible with current CMP tools.

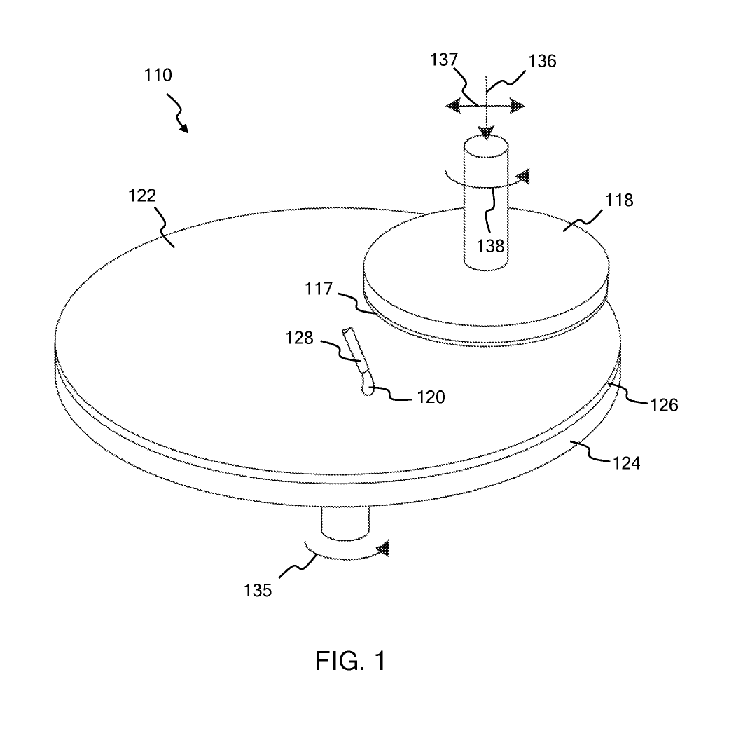

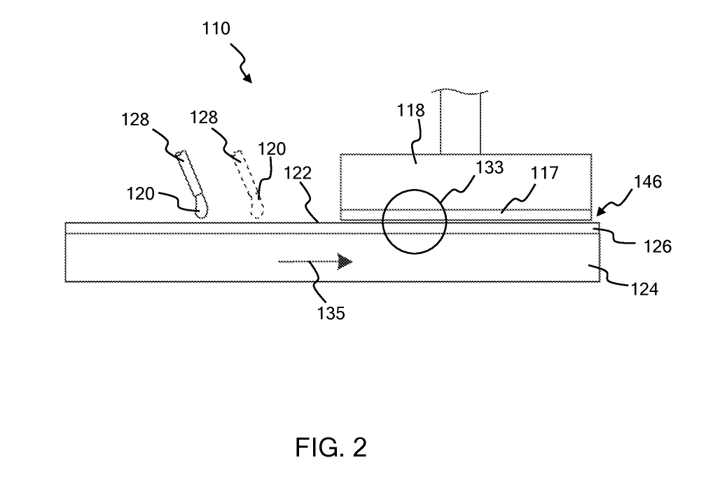

FIG. 1 shows an embodiment of chemical-mechanical planarization tool 110 according to the invention. FIG. 2 shows a side view of CMP tool 110 of FIG. 1. Some of the parts and interconnections of CMP tool 110 are not shown for simplicity and clarity. CMP tool 110 of FIG. 1 is used to planarize semiconductor wafer 117. In some embodiments CMP tool 110 according to the invention is used to polish semiconductor wafer 117. In some embodiments CMP tool 110 according to the invention is used to polish or planarize other types of work pieces.

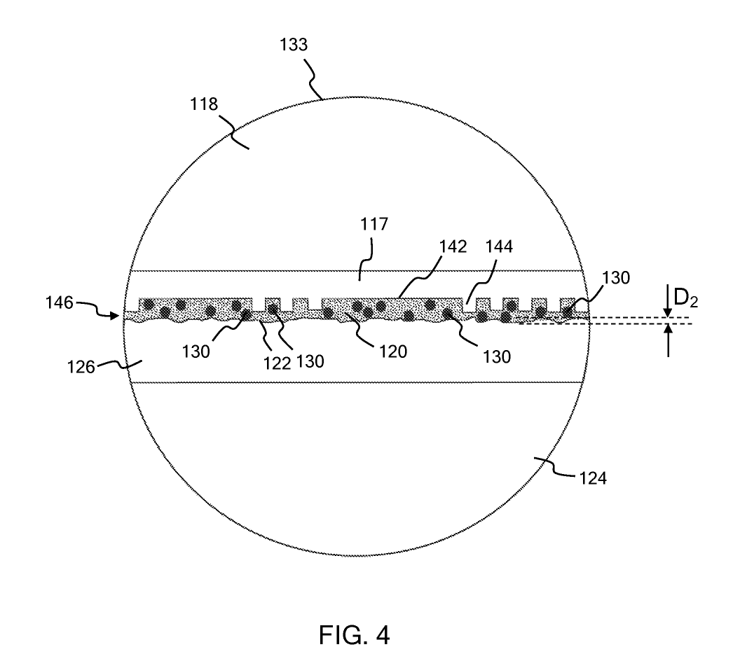

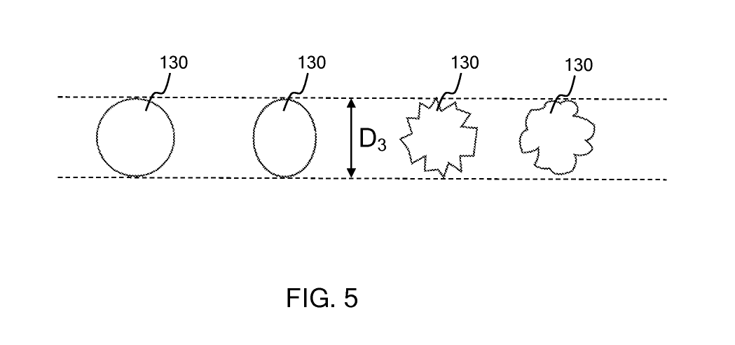

CMP tool 110 according to the invention includes slurry mixture 120 according to the invention, and counter-face 122 which holds slurry mixture 120 against semiconductor wafer 117. Slurry mixture 120 according to the invention includes slurry beads 130 (see FIG. 4 and FIG. 5), where slurry beads 130 are formed of a polymer material. In some embodiments slurry beads 130 each have a diameter of between 0.1 and 1000 microns, as will be explained in more detail later. Slurry mixture 120 according to the invention of FIG. 1 is applied to counter-face 122 using slurry nozzle 128. A counter-face is a face or surface which counters—or opposes—another surface. In CMP tool 110 according to the invention counter-face 122 opposes wafer 117. In some embodiments more than one slurry nozzle 128 is used, as shown in FIG. 2 with an optional second slurry nozzle 128. In some embodiments of CMP tool 110 according to the invention, one or more slurry nozzles are used to apply a conventional slurry mixture that does not contain slurry beads 130 to counter-face 122, and a second set of one or more than one slurry nozzles are used to apply slurry beads 130 to counter-face 122.

In the embodiment of CMP tool 110 shown in FIG. 1, polishing head 118 holds semiconductor wafer 117 against polishing layer 126. Polishing head 118 exerts pressure 136 on wafer 117. In this embodiment polishing layer 126 includes counter-face 122, which will be discussed shortly. Polishing layer 126 sits on platen 124. Platen 124 in this embodiment rotates in direction 135. Polishing head 118 in this embodiment rotates in direction 138 and moves laterally in direction 137. The movement of platen 124 and polishing head 118 provide relative movement between counter-face 122 and wafer 117, which accomplishes the mechanical polishing effect. In some embodiments, platen 124 and polishing head 118 provide relative movement between polishing layer 126 and wafer 117 by other means.

In the embodiment of CMP tool 110 of FIG. 1 and FIG. 2, slurry nozzle 128 releases slurry mixture 120 onto counter-face 122. Slurry mixture 120 enters gap 146 between surface to be polished 142 of semiconductor wafer 117 (see FIG. 4) and counter-face 122, where slurry mixture 120 assists in polishing of surface to be polished 142. In some embodiments of CMP tool 110 according to the invention, slurry mixture 120 is applied using other means and methods.

In the embodiment of CMP tool 110 of FIG. 1, polishing layer 126 includes counter-face 122 according to the invention. Counter-face 122 in this embodiment is formed of polycarbonate, but the invention is not limited in this aspect, as will be discussed in further detail shortly. Counter-face 122 according to the invention is the surface which opposes semiconductor wafer 117, the surface which holds slurry mixture 120, with slurry beads 130, against semiconductor wafer 117.

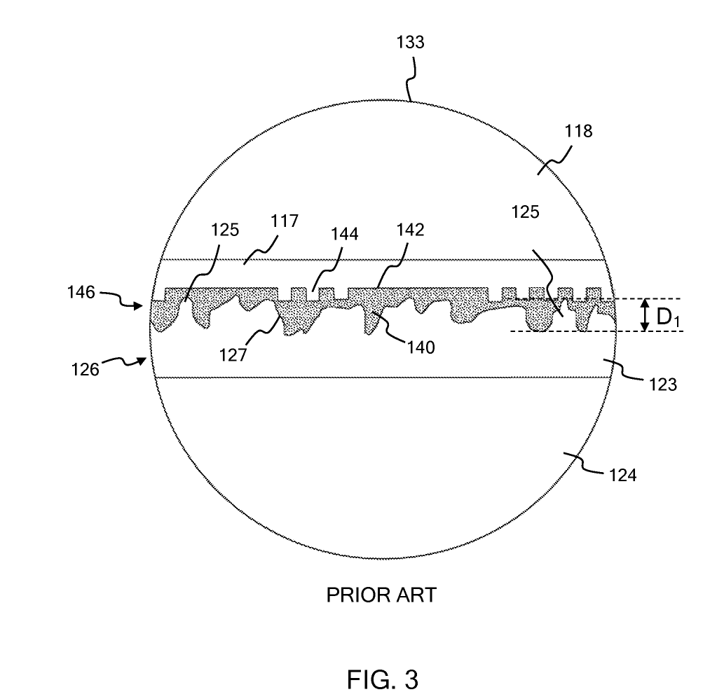

FIG. 3 shows how section 133 of FIG. 2 would look using a prior art CMP tool where polishing layer 126 includes polishing pad 123 with polishing surface 127, and slurry 140 is used instead of slurry 120 according to the invention. Semiconductor wafer 117 includes surface to be polished 142 which includes features 144 that are to be polished (removed) by the CMP tool being utilized. Semiconductor wafer 117 is held by polishing head 118. Polishing pad 123 is coupled to platen 124. Polishing pad 123 includes polishing surface 127 which includes asperities 125 (two of several labeled) that polish surface 142. Asperities 125 are also called summits or peaks and are the protrusions on polishing pad 123 that come into contact with wafer 117 and which remove features 144. Asperities 125 include diamond tips or edges in some cases. Polishing surface 127, which includes asperities 125, polishes surface to be polished 142 in conjunction with slurry mixture 140. Slurry mixture 140 can include water, chemicals and nanoparticles that contribute to the abrasive nature of the contact between polishing pad 123 and wafer 117. In current art the nanoparticles that may be included in slurry mixture 140 have a much smaller diameter than the average height of an asperity 125 that comes in contact with surface to be polished 142. The average diameter of the nanoparticles is 1 to 100 nanometers (nm). The average height D₁ of asperities 125 that come into contact with surface to be polished 142 is 10 to 50 microns. Nanoparticles included in conventional slurry mixture 140 are often formed of silica or alumina.

FIG. 4 shows close-up section 133 of FIG. 2, which includes the interface between semiconductor wafer 117 and counter-face 122 of CMP tool 110 according to the invention as shown in FIG. 1 and FIG. 2. In this embodiment semiconductor wafer 117 with surface to be polished 142 and features 144 face counter-face 122. Counter-face 122 according to the invention is smoother than polishing surface 127. Polishing surface 127 has asperities 125 with an average height D₁ of about 10 to 50 microns. Counter-face 122 in some embodiments has texture features that have a height D₂ of about 10 to 100 nm. Polishing slurry 120 according to the invention enters gap 146 between wafer 117 and polishing layer 126. Polishing slurry 120 according to the invention includes slurry beads 130 (three of numerous labeled). Slurry beads 130 do the job of asperities 125, in other words slurry beads 130 remove features 144 on surface to be polished 142. Slurry beads 130 slide or roll across surface to be polished 142 as counter-face 122 moves with respect to surface to be polished 142. Slurry beads 130 are held against surface to be polished 142 by counter-face 122. As slurry beads 130 are rolled or slid along surface to be polished 142 by the relative motion between surface to be polished 142 and counter-face 122, slurry beads 130 remove features 144 and in general provide the polishing and/or planarization action that was previously obtained from asperities 125.

In some embodiments counter-face 122 and/or slurry beads 130 are treated so that they develop an opposing static or surface charge so that there is an attractive force between them. In these embodiments slurry beads develop a slurry bead static or surface charge, and counter-face 122 develops a counter-face static or surface charge, where the slurry bead static charge and the counter-face static charge are of opposite polarity. Thus slurry beads 130 and counter-face 122 are attracted to one another. In some embodiments slurry beads 130 and/or counter-face 122 are treated so that they develop an attractive force between them that is different from a static charge, such as a chemical attractive force or other type of attractive force. Having slurry beads 130 and counter-face 122 develop an attractive force between them helps hold slurry beads 130 onto counter-face 122 during the polishing process.

CMP tool 110 according to the invention includes slurry mixture 120, where slurry mixture 120 includes slurry beads 130. Slurry beads 130 according to the invention are formed of a polymer material. In some embodiments slurry beads 130 are formed of a man-made polymer material. In some embodiments slurry beads 130 each have a diameter of between 0.1 and 1000 microns. In some embodiments slurry beads 130 each have a diameter of between 1 and 100 microns. CMP tool 110 shown in the figures includes counter-face 122, but the invention is not limited in this aspect. In some embodiments CMP tool 110 uses slurry mixture 120 according to the invention with a conventional polishing pad 123. In some embodiments CMP tool 110 uses other types of polishing layers 126.

Slurry beads 130 according to the invention can take many different shapes and forms. Several embodiments of slurry beads 130 are shown in FIG. 5, which shows a cross-section of four different embodiments of slurry beads 130. In the embodiment of slurry beads 130 shown in FIG. 4 and FIG. 5, slurry beads 130 each have a diameter D₃ of between 10 and 50 microns. Slurry beads 130 are shown in FIG. 4 as having a round shape, but slurry beads 130 are not limited in this aspect, as shown in FIG. 5. FIG. 5 shows examples of several types of slurry beads 130, but slurry beads 130 are not limited to these shapes or forms. Slurry beads 130 can have any shape and surface texture. In some embodiments slurry beads 130 are ovoid-shaped. In some embodiments slurry beads 130 each have a diameter D₃ of between 0.1 and 1000 microns. In some embodiments slurry beads 130 each have a diameter D₃ of between 1 and 100 microns. In some embodiments slurry beads 130 each have approximately the same diameter D₃. In some embodiments slurry beads 130 each have a diameter D₃ approximately equal to the distance between counter-face 122 and semiconductor 117. In some embodiments slurry beads 130 each have a diameter approximately equal to the distance between counter-face 122 and another type of work piece that is being polished or planarized.

The shape and form of slurry beads 130 according to the invention is not particularly limited and the material used for slurry beads 130 may be any durable material that is flexible enough to withstand the pressures involved in CMP and at the same time is chemically stable in the respective chemical environments in which CMP is carried out. Slurry beads 130 made of plastic, ceramic, glass, mineral, metal or the like may be used. In some embodiments slurry beads 130 are formed from a polymer material. In some embodiments slurry beads 130 are formed from a man-made polymer material. Using a man-made polymer material for slurry beads 130 allows the size, shape, and hardness of slurry beads 130 to be engineered to provide optimum polishing characteristics. In some embodiments the man-made polymer material used for slurry beads 130 is chose to fit the material that is to be polished. In some embodiments slurry beads 130 are formed from polyurethane. In some embodiments slurry beads 130 include polyurethane. In some embodiments slurry beads 130 are formed from a compressible material. Compressible means that the size or shape of the slurry beads can be changed, by pressure for example. A compressible material is a material that can be compacted or molded—the material possesses a variable size or shape. In some embodiments slurry beads 130 include a compressible material.

Slurry beads 130 of the invention, and especially the active slurry beads 130 (those involved in polishing) are compressed between surface to be polished 42 of wafer 117 and counter-face 122 of polishing layer 126 as shown in FIG. 4. Slurry beads 130 slide or roll along surface to be polished 142. In some embodiments it is desirable for slurry beads 130 to be formed from or include a compressible material.

The size of slurry beads 130 according to the invention correspond roughly to the dimensions of asperities 125 on commercial polishing pads 123 sought to be replaced by the invention. In some embodiments slurry beads 130 each have a diameter D₃ of between 0.1 and 1000 microns. In some embodiments slurry beads 130 each have a diameter D₃ of between 1 and 100 microns. In some embodiments slurry beads 130 each have a diameter D₃ of between 10 and 50 microns. In some embodiments slurry beads 130 each have approximately the same diameter D₃. In some embodiments slurry beads 130 each have a diameter D₃ approximately equal to the distance between counter-face 122 and semiconductor 117. Surry beads 130 may be uniform in size or they may vary either in two or more discrete variations of size in any proportion or quantity. The distribution of sizes of slurry beads 130 may be continuous or irregular, and where distribution of size is irregular, slurry bead 130 size distributions are not particularly limited, however, slurry bead 130 size distributions represented by Gaussian curves corresponding roughly to the distribution of dimensions of asperities 125 on commercial polishing pads 123 are used in some embodiments.

The shape of slurry beads 130 according to the invention is not particularly limited and slurry beads 130 may be in any shape or configuration including even or uneven and asymmetric shapes. Non-angular or angular shapes may be used without limitation, as shown in the example slurry beads 130 in FIG. 5. Among non-angular shapes spherical or ovoid shaped slurry beads 130 are used in some embodiments.

The roughness of the surface of slurry beads 130 is not particularly limited. In some embodiments the surface of slurry beads 130 is smooth. In some embodiments the surface of slurry beads 130 is rough.

The concentration of slurry beads 130 in slurry 120 is not particularly limited and any suitable concentration value may be used. In some embodiments the concentration of slurry beads 130 in slurry 120 is determined by the area density required on counter-face 122 at a given load. In some embodiments slurry beads 130 comprise between 0.001 and 30 weight percent of slurry mixture 120. In some embodiments slurry beads 130 comprise between 0.1 and 30 weight percent of slurry mixture 120. In some embodiments slurry beads 130 comprise between 5 and 20 weight percent of slurry mixture 120.

The composition of slurry mixture 120, besides slurry beads 130, can take many different forms. Slurry mixtures 120 that easily wet and suspend slurry beads 130 without surfactants or other agents are used in some embodiments. The range of concentrations that may be used is very large. The variability in asperity 125 topography versus the diameter of slurry beads 130 may be correspondingly large as well. In some embodiments the slurry bead 130 surface character as opposed to slurry 120 and counter-face 122 characteristics determines what weight percent of slurry beads 130 may optimize polishing effects. In some embodiments a surfactant is used to suspend slurry beads 130 in slurry mixture 120. The surfactant used to suspend slurry beads 130 in slurry 120 is not particularly limited and may be a commercially available surfactant like Tweon 20 or the like.

In the embodiment of CMP tool 110 of FIG. 1, FIG. 2, and FIG. 4, CMP tool 110 includes counter-face 122 according to the invention. Counter-face 122 according to the invention is the surface which opposes semiconductor wafer 117, the surface which holds slurry mixture 120 against semiconductor wafer 117. Counter-face 122 in this embodiment is formed of polycarbonate, but the invention is not limited in this aspect. Counter-face 122 can be formed of any plastic, ceramic, mineral, metal or other suitable material. In this embodiments counter-face 122 is formed of poly-carbonate. In some embodiments counter-face 122 is formed of quartz. In some embodiments counter-face 122 is formed of polyurethane. In some embodiments counter-face 122 is polishing pad 123 used in a conventional CMP process. In some embodiments counter-face 122 is formed of other materials. The shape of counter-face 122 is not particularly limited. In the embodiment of CMP tool 110 of FIG. 1, counter-face 122 has a circular disc shape. In some embodiments counter-face 122 is a smooth solid object. In some embodiments counter-face 122 is a conventional pad with a skived (shaved or pared—thin layers removed), or planarized surface. In some embodiments counter-face 122 has a roughened surface. In some embodiments counter-face 122 is a plastic or polymer. In some embodiments counter-face 122 has a matrix or grid pattern on it to grab and roll slurry beads 130.

The size of counter-face 122 of the invention is not particularly limited. In some embodiments counter-face 122 is smaller than the polishing pad 123 that counter-face 122 is replacing on the relevant CMP tool, or smaller than wafer 117. In some embodiments counter-face 122 is the same size as the polishing pad it is replacing.

The means of attachment of counter-face 122 of the invention to CMP tool 110 is not particularly limited. In some embodiments the attachment of counter-face 122 to polishing platen 124 is accomplished in the same way that a commercial polishing pad 123 is attached to platen 124, such as by using a double-sided adhesive film. The distance between counter-face 122 and the wafer 117 during the polishing or planarization process can take many different values. In some embodiments slurry beads 130 have a diameter approximately equal to the distance between counter-face 122 and wafer 117.

In some embodiments of CMP tool 110, counter-face 122 is hydrophilic. In some embodiments of CMP tool 110 counter-face 122 is hydrophobic. Counter-face 122 of the invention may develop a counter-face static or surface charge that will attract slurry beads 130. In some embodiments slurry beads 130 develop a slurry bead static or surface charge with a polarity that is opposite to the polarity of the counter-face static or surface charge. The opposing polarity static charge or surface charges of counter-face 122 and slurry beads 130 enhances the attractive force between counter-face 122 and slurry beads 130. In some embodiments counter-face 122 is treated such that counter-face 122 develops an attractive force between itself and slurry beads 130 that is different than a static charge attractive force. In a modification upon the process of the invention, counter-face 122 is wetted by slurry mixture 120 and then slurry beads 130 are deposited on counter-face 122 at a slow rate. In this case, many of them then encounter wafer 117 during CMP and perform polishing.

Since slurry beads 130 are deposited continuously and active slurry beads 130 can be crushed or deformed by wafer 117, slurry bead 130 removal from counter-face 122 may be necessary. The means of accomplishing slurry bead 130 removal from counter-face 122 is not particularly limited. In some embodiments removal is accomplished by means of a soft brush, which would replace the pad conditioner used in a conventional CMP process.

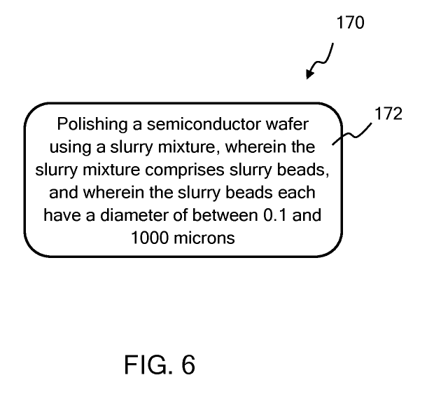

FIG. 6 illustrates method 170 of polishing a semiconductor wafer using a CMP tool. Method 170 includes step 172 of polishing the semiconductor wafer using a slurry mixture, where the slurry mixture contains slurry beads. The slurry beads each have a diameter of between 0.1 and 1000 microns. In some embodiments the slurry beads each have a diameter of between 1 and 100 microns. In some embodiments the slurry beads each have a diameter of between 10 and 50 microns. In some embodiments the CMP tool includes a counter-face, where the counter-face is formed of polycarbonate. In some embodiments the counter-face is formed of quartz. In some embodiments the counter-face is formed of other materials. In some embodiments the counter-face is hydrophilic. In some embodiments method 170 includes the step of removing slurry beads from the counter-face with a soft brush.

In some embodiments method 170 includes other steps. In some embodiments method 170 includes the step of treating the counter-face such that an attractive force is generated between the counter-face and the slurry beads. In some embodiments method 170 includes converting a prior art CMP tool to a CMP tool according to the invention. In some embodiments method 170 includes the step of removing the polishing pad from a prior art CMP tool. In some embodiments method 170 includes the step of installing a counter-face in place of the polishing pad.

In some embodiments the slurry beads each have a diameter approximately equal to the distance between the counter-face and the semiconductor wafer. In some embodiments the slurry beads are formed of a polymer material. In some embodiments the slurry beads are formed of a man-made polymer material. In some embodiments the slurry beads comprise between 0.001 and 30 weight percent of the slurry mixture. In some embodiments the slurry beads comprise between 0.1 and 30 weight percent of the slurry mixture. In some embodiments the slurry beads comprise between 5 and 20 weight percent of the slurry mixture. In some embodiments the slurry beads include polyurethane. In some embodiments the slurry beads each have approximately the same diameter. In some embodiments the slurry beads are ovoid shaped. In some embodiments the slurry beads are spherical in shape. In some embodiments the slurry beads are formed of a compressible material.

### EXAMPLES

The following examples are meant to be exemplary in nature and do not represent limitations on the invention.

About 1 kg of high-grade 15 micron polyurethane slurry beads 130 and several commercial slurries mixtures 120 with different pH values and chemical compositions were obtained and used in the practice examples of the invention. Determination of the ability of a particular commercial slurry 120 to suspend slurry beads 130 evenly was determined by means of a beaker and a stirring unit. About 50 grams of slurry beads 130 were placed in 200 ml of slurry 120 and the mixtures were stirred for 10 minutes. Slurry beads 130 were also tested to confirm that they would not flock on the surface. Although commercial slurries 120 may not naturally support a suspension of slurry beads 130, a minimal amount, eg 1-5 ml/liter, of a surfactant, such as Tweon 20 or other additive to help promote suspension may be added with or without stirring to effect even suspension of slurry beads 130. In this way, a commercial slurry 120 requiring the least modification may be selected.

At the end of this initial step, slurry beads 130 were suspended in a relatively stable smooth suspension with no flocking and a low settlement rate.

Several materials were used for counter-face 122 to determine which would be unsuitably hydrophilic, as measured by the slurry 120 contact angle with the material, to determine which materials might make a superior counter-face 122.

Using a beaker test it was determined whether in the presence of slurry 120 the counter-face 122 material has a surface charge that promotes or retards slurry bead 130 adsorption. For 15 micron slurry beads 130, the determination can be made with optical microscopy. A test was carried out to assess the difficulty with which adsorbed slurry beads 130 are removed from counter-face 122 with a soft brush.

Several counter-faces 122 were prepared for use on an R&D polishing tool. Concentric grooving of counter-face 122 was used. Then a series of polishing experiments at a single polishing pressure and sliding speed under conditions used in commercial polishing to measure the blanket material removal rate of either silicon dioxide or copper, depending on the slurry selected, were conducted.

### EFFECTS OF THE INVENTION

In addition to the advantage of the reduction of defects in the product semiconductor wafers already referred to above, from an environmental perspective, pad debris in the liquid waste stream that has a distribution of sizes ranging from submicron to tens of microns in the conventional process is traded for polyurethane slurry beads 130 in the waste stream that have a much tighter size distribution. The latter may therefore be more easily filtered or made to float, via an anti-wetting agent, thus allowing easy recovery of slurry beads 130. In addition, it is possible to hold the mass fraction of slurry beads 130 to a value no greater than the mass fraction of debris currently in the waste slurry, so that the rate of waste production in the modified process will not increase over the current process. Controlling the size and usage rate and filtering or removing the waste will help to ensure that slurry beads 130 do not enter the environment, such as rivers and oceans.

Since the method of polishing a semiconductor wafer according to the invention does not require periodic disposal of ⅔ of the original polishing pad, there will be a net reduction in polyurethane use by a factor of 3. Slurry beads 130 are also cheaper and much easier to produce and transport than polyurethane polishing pads, so there are additional economic and environmental benefits to their use. Furthermore, with conventional polishing pads, both the asperities as well as the land and valley areas act as absorption sites for unwanted and environmentally harmful polishing by-products such as copper and ruthenium and in the future, arsenic. These elements remain within the pad matrix after the pad has been decommissioned and discarded in landfills. On the other hand, slurry beads 130, having a much lower number of absorption sites for the metallic by-products, will likely force the by-products to remain in solution and be subsequently treated by electro-coagulation or other chelating or sedimentation means. Similarly, the modified process will replace a technologically complex diamond pad conditioner, which uses artificial diamonds and is made using processes that include electroplating, sintering, brazing or chemical vapor deposition. The method according to the invention can include removing beads 130 from counter-face 122 with a soft brush, and thus the method replaces the pad conditioner itself with a soft brush.

The embodiments and examples set forth herein were presented in order to best explain the present invention and its practical application and to thereby enable those of ordinary skill in the art to make and use the invention. However, those of ordinary skill in the art will recognize that the foregoing description and examples have been presented for the purposes of illustration and example only. The description as set forth is not intended to be exhaustive or to limit the invention to the precise form disclosed. Many modifications and variations are possible in light of the teachings above.

1. A slurry mixture for use with a chemical-mechanical planarization (CMP) tool, the slurry mixture comprising slurry beads, wherein the slurry beads comprise a polymer material.

2. The slurry mixture of claim 1, wherein the slurry beads each have a diameter of between 0.1 and 1000 microns.

3. The slurry mixture of claim 1, wherein the slurry beads each have a diameter of between 10 and 50 microns.

4. The slurry mixture of claim 1, wherein the slurry beads comprise polyurethane.

5. The slurry mixture of claim 1, wherein the slurry beads comprise between 0.001 and 30 weight percent of the slurry.

6. The slurry mixture of claim 1, wherein the slurry beads comprise between 5 and 20 weight percent of the slurry.

7. A chemical-mechanical planarization (CMP) tool for polishing a semiconductor wafer, wherein the CMP tool comprises:
a slurry mixture comprising slurry beads, wherein the slurry beads each have a diameter of between 0.1 and 1000 microns; and
a counter-face, wherein the counter-face holds the slurry beads against the semiconductor wafer.

8. The tool of claim 7, wherein the slurry beads are formed of a man-made polymer material.

9. The tool of claim 7, wherein the slurry beads each have a diameter of between 1 and 100 microns.

10. The tool of claim 7, wherein the counter-face is formed of polycarbonate.

11. The tool of claim 7, wherein the counter-face is formed of quartz.

12. The tool of claim 7, wherein the slurry beads comprise a slurry bead static or surface charge with a polarity opposite to a polarity of a counter-face static or surface charge of the counter-face.

13. The tool of claim 7, wherein the slurry beads each have a diameter approximately equal to the distance between the counter-face and the semiconductor wafer.

14. A method of polishing a semiconductor wafer using a chemical-mechanical planarization (CMP) tool, the method comprising the step of polishing the semiconductor wafer using a slurry mixture, wherein the slurry mixture comprises slurry beads, and wherein the slurry beads each have a diameter of between 0.1 and 1000 microns.

15. The method of claim 14, wherein the CMP tool comprises a counter-face formed of polycarbonate.

16. The method of claim 15, further comprising the step of treating the counter-face such that an attractive force is generated between the counter-face and the slurry beads.

17. The method of claim 15, wherein the slurry beads each have a diameter approximately equal to the distance between the counter-face and the semiconductor wafer.

18. The method of claim 14, wherein the slurry beads each have a diameter of between 10 and 50 microns.

19. The method of claim 14, wherein the slurry beads comprise between 0.001 and 30 weight percent of the slurry mixture.

20. The method of claim 14, further comprising the steps of:
removing a polishing pad from the CMP tool;
and
installing a counter-face in place of the polishing pad.
